(19) United States
(12) Patent Application Publication
(10) Pub. No.: US 2016/0284565 A1
(43) Pub. Date: Sep. 29, 2016

(54) SEMICONDUCTOR DEVICE MANUFACTURING METHOD

(71) Applicant: RENESAS ELECTRONICS CORPORATION, Tokyo (JP)

(72) Inventor: Eiji ONO, Gunma (JP)

(21) Appl. No.: 15/060,334

(22) Filed: Mar. 3, 2016

(30) Foreign Application Priority Data
Mar. 27, 2015 (JP) 2015-067633

(51) Int. Cl. H01L 21/48; H01L 21/56; H01L 23/495; H01L 23/29

(52) U.S. Cl. CPC H01L 21/4825; H01L 23/293; H01L 21/56; H01L 23/49541

(57) ABSTRACT

A semiconductor device manufacturing method which enhances the reliability of the semiconductor device. The method uses a lead frame (hoop) which includes a first suspension lead and a second suspension lead. Each of the suspension leads has a narrow part which has a smaller width than at least any one of a first lead, a second lead, and a tie bar. If a tensile stress is applied to the first suspension lead or second suspension lead, the narrow parts reduce the stress. This relieves the stress on the first lead, the second lead and the base of a sealing member, thereby reducing the possibility of package cracking or package chipping. As a result, the reliability of the semiconductor device is enhanced.

### CROSS-REFERENCE TO RELATED APPLICATIONS

The disclosure of Japanese Patent Application No. 2015-067633 filed on Mar. 27, 2015 including the specification, drawings and abstract is incorporated herein by reference in its entirety.

### BACKGROUND

The present invention relates to a semiconductor device manufacturing method and more particularly to a technique useful for assembling a flat-lead semiconductor device.

In assembling a semiconductor device using a hoop lead frame (hereinafter sometimes called simply a hoop), the assembling process is performed while the hoop is wound around a reel. Regarding the outer frames at both ends of the hoop, post leads are joined to one outer frame and die island leads are joined to the other outer frame.

For example, Japanese Unexamined Patent Application Publication No. 2003-46051 discloses a lead frame structure in which a die pad over which a semiconductor chip is mounted is directly joined to suspension pins.

### SUMMARY

In the assembling process using a hoop lead frame as mentioned above, the post leads or die island leads may be pulled due to vibrations during product transportation as caused by unevenness in hoop sprocket size (including vibrations during manufacture as caused by variation in the manufacturing technique used in manufacturing equipment) or due to vibrations, impact, etc. which may occur while a worker handles products (semiconductor devices).

This may cause cracking or chipping in the sealing member of the semiconductor device. The present inventors examined the above lead frame structure and found that cracking 20 or chipping 30 occur mainly in the interface between the sealing member (resin) 4 and the lead 50 in the semiconductor device 60 as illustrated in FIGS. 30 and 31 which show comparative examples.

If cracking or chipping occurs in this way, the reliability of the semiconductor device may decline.

The above and further objects and novel features of the invention will more fully appear from the following detailed description in this specification and the accompanying drawings.

According to one aspect of the present invention, there is provided a semiconductor device manufacturing method which includes the steps of: (a) providing a lead frame having a first lead including a chip mounting area, a second lead, a first suspension lead, and a second suspension lead; (b) mounting a semiconductor chip over the chip mounting area; (c) coupling the semiconductor chip and the second lead electrically; and (d) sealing the semiconductor chip with resin. The lead frame further has frame parts at both ends and a plurality of bar leads. The first suspension lead has a first part joining the adjacent bar leads and a second part intersecting the first part and joining the first lead. The second suspension lead has a third part joining the adjacent bar leads and a fourth part intersecting the third part and joining the second lead. The first suspension lead and the second suspension lead each have a narrow part with a smaller width than at least any one of the first lead, the second lead, and the bar lead.

According to another aspect of the present invention, there is provided a semiconductor device manufacturing method which includes the steps of: (a) providing a lead frame having a first lead including a chip mounting area, a second lead, a first support lead, and a second support lead; (b) mounting a semiconductor chip over the chip mounting area; (c) coupling the semiconductor chip and the second lead electrically; and (d) sealing the semiconductor chip with resin. The lead frame further has frame parts at both ends and a plurality of bar leads. The first support lead has a narrow part or crank part which joins the adjacent bar leads and has a smaller width than at least any one of the first lead and the bar lead. The second support lead has a narrow part or crank part which joins the adjacent bar leads and has a smaller width than at least either of the second lead and the bar lead.

According to the present invention, the reliability of the semiconductor device can be enhanced.

### BRIEF DESCRIPTION OF THE DRAWINGS

FIG. 1 is a plan view showing an example of the structure of a semiconductor device according to an embodiment;

FIG. 2 is a back view showing an example of the structure of the semiconductor device shown in FIG. 1;

FIG. 3 is a sectional view showing an example of the structure, taken along the line A-A in FIG. 1;

FIG. 4 is a plan view of the main part of the semiconductor device shown in FIG. 1 as seen through a sealing member;

FIG. 5 is a flowchart showing an example of the sequence of assembling the semiconductor device shown in FIG. 1;

FIG. 6 is a fragmentary plan view showing an example of the lead frame used to assemble the semiconductor device shown in FIG. 1;

FIG. 7 is an enlarged fragmentary plan view showing an example of the structure of area A shown in FIG. 6;

FIG. 8 is a fragmentary sectional view showing an example of the structure, taken along the line A-A in FIG. 7;

FIG. 9 is a fragmentary plan view showing an example of the structure after die bonding in the process of assembling the semiconductor device shown in FIG. 1;

FIG. 10 is a fragmentary sectional view showing an example of the structure, taken along the line A-A in FIG. 9;

FIG. 11 is a fragmentary plan view showing an example of the structure after wire bonding in the process of assembling the semiconductor device shown in FIG. 1;

FIG. 12 is a fragmentary sectional view showing an example of the structure, taken along the line A-A in FIG. 11;

FIG. 13 is a fragmentary plan view showing an example of the structure after molding in the process of assembling the semiconductor device shown in FIG. 1;

FIG. 14 is a fragmentary sectional view showing an example of the structure, taken along the line A-A in FIG. 13;

FIG. 15 is a schematic view showing an example of the integrated apparatus used in the integrated hoop assembling line for the semiconductor device shown in FIG. 1;

FIG. 16 is a fragmentary sectional view showing an example of the structure during deburring in the process of assembling the semiconductor device shown in FIG. 1;

FIG. 17 is a fragmentary sectional view showing an example of the structure after coating in the process of assembling the semiconductor device shown in FIG. 1;

FIG. 18 is a schematic view showing an example of the deburring apparatus used in the deburring line in the process of assembling the semiconductor device shown in FIG. 1;

FIG. 19 is a schematic view showing an example of the solder coating apparatus used in the coating line in the process of assembling the semiconductor device shown in FIG. 1;

FIG. 20 is a schematic view showing an example of the laser marking apparatus used in the marking line in the process of assembling the semiconductor device shown in FIG. 1;

FIG. 21 is a schematic view showing an example of the integrated apparatus used in the lead cutting, sorting and taping line for assembling the semiconductor device shown in FIG. 1 using a hoop;

FIG. 22 is a fragmentary plan view showing an advantageous effect of the process of assembling the semiconductor device shown in FIG. 1;

FIG. 23 is a fragmentary plan view showing an advantageous effect of the process of assembling the semiconductor device shown in FIG. 1;

FIG. 24 is a side view showing an advantageous effect of the lead structure shown in FIG. 23;

FIG. 25 is a fragmentary plan view showing an advantageous effect of the process of assembling the semiconductor device shown in FIG. 1;

FIG. 26 is a side view showing an advantageous effect of the lead structure shown in FIG. 25;

FIG. 27 is a fragmentary plan view showing a first variation of the lead frame used to assemble the semiconductor device according to the embodiment;

FIG. 28 is a fragmentary plan view showing a second variation of the lead frame used to assemble the semiconductor device according to the embodiment;

FIG. 29 is an enlarged fragmentary plan view showing an example of the structure of area A shown in FIG. 28;

FIG. 30 is a back view showing the back structure of a semiconductor device as a comparative example; and

FIG. 31 is a back view showing the back structure of a semi conductor device as a comparative example.

### DETAILED DESCRIPTION

As for the preferred embodiments of the invention as described below, basically the same or similar elements or matters will not be repeatedly described except when necessary.

The preferred embodiments of the present invention may be described in different sections or separately as necessary or for the sake of convenience, but the embodiments described as such are not irrelevant to each other unless otherwise expressly stated. One embodiment may be, in whole or in part, a modified, detailed or supplementary form of another.

As for the preferred embodiments as described below, when numerical information for an element (the number of pieces, numerical value, quantity, range, etc.) is indicated by a specific number, it is not limited to the specific number unless otherwise specified or theoretically limited to that number; it may be larger or smaller than the specific number.

In the preferred embodiments as described below, constituent elements (including constituent steps) are not necessarily essential unless otherwise specified or theoretically essential.

In the preferred embodiments as described below, as for constituent elements, it is obvious that the expression “comprising A (element)”, “comprised of A”, “having A”, or “including A” does not exclude another element unless exclusion of another element is expressly stated. Similarly, in the preferred embodiments as described below, when a specific form or positional relation is indicated for an element, it should be interpreted to include a form or positional relation which is virtually equivalent or similar to the specific form or positional relation unless otherwise specified or theoretically limited to the specific form or positional relation. The same is true for the above numerical values and ranges.

Next, the preferred embodiments will be described in detail referring to the accompanying drawings. In all the drawings that illustrate the preferred embodiments, members with like functions are designated by like reference numerals and repeated descriptions thereof are omitted. For easy understanding, hatching may be used even in a plan view.

### Embodiments

### Structure of the Semiconductor Device

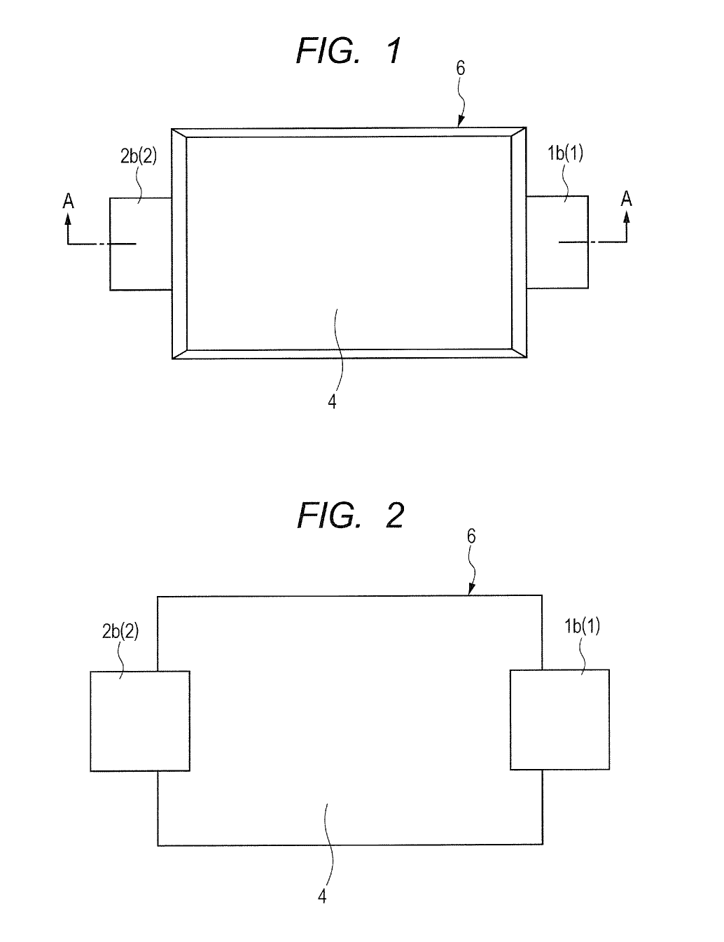

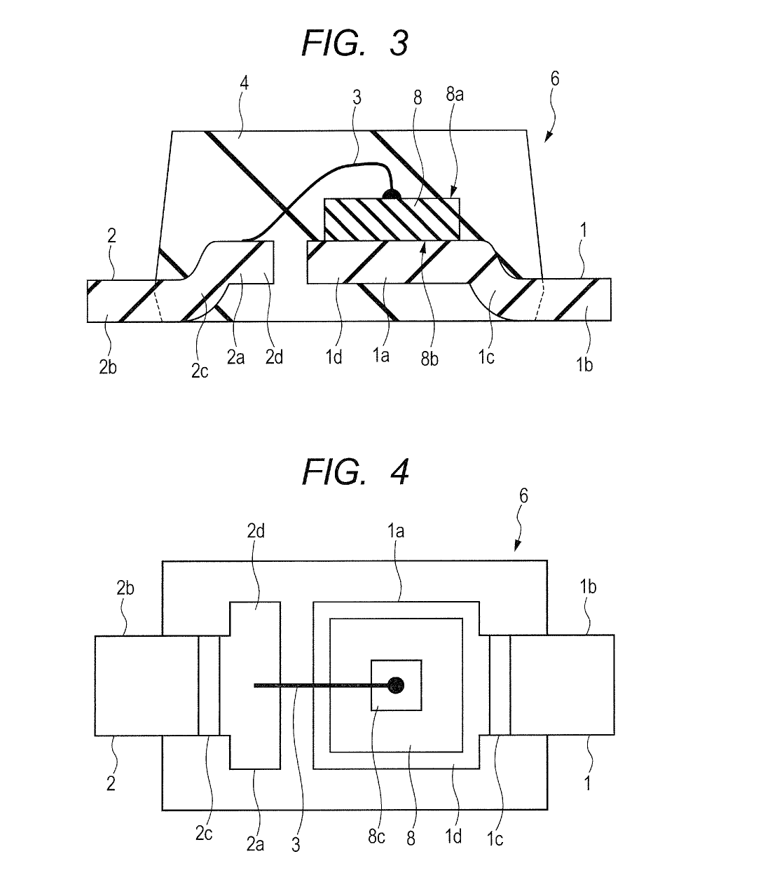

The structure of a semiconductor device according to an embodiment will be described referring to FIGS. 1 to 4. FIG. 1 is a plan view showing an example of the structure of the semiconductor device according to the embodiment; FIG. 2 is a back view showing an example of the structure of the semiconductor device shown in FIG. 1; FIG. 3 is a sectional view showing an example of the structure, taken along the line A-A in FIG. 1; and FIG. 4 is a plan view of the main part of the semiconductor device shown in FIG. 1 as seen through a sealing member.

The semiconductor device 6 according to this embodiment includes a pair of leads spaced by a given distance and located opposite to each other: a first lead (also called a die island lead) 1 and a second lead (also called a post lead) 2. The first lead 1 includes a chip mounting area 1d and a semiconductor chip 8 is mounted over the chip mounting area 1d. The semiconductor chip 8 has a main surface (circuit formation surface) 8a and a back surface 8b opposite to it and the back surface 8b of the semiconductor chip 8 and the upper surface of the chip mounting area 1d are electrically coupled by gold-tin (Au—Sn) eutectic bonding.

A pad electrode (electrode pad, bonding electrode, bonding pad) 8c is formed on the main surface 8a of the semiconductor chip 8.

The semiconductor device 6 includes the semiconductor chip 8, a wire 3 for coupling the second lead 2 and the pad electrode 8c of the semiconductor chip 8 electrically, and a sealing member 4 for sealing part of the first lead 1, part of the second lead 2, the semiconductor chip 8, and the wire 3.

The first lead 1 and second lead 2 are formed, for example, by pressing a thermally conductive thin sheet metal of copper, iron, phosphor bronze or the like, for example, with a thickness of about 0.1 to 0.3 mm. The first lead 1 functions as a die bond electrode and the second lead 2 functions as a wire bond electrode.

As shown in FIG. 3, the first lead 1 includes a first inner part 1a, which is also the chip mounting area 1d, a first outer part 1b, and a first offset part 1c between the first inner part 1a and first outer part 1b. The first inner part 1a is located above the first outer part 1b (toward the upper surface of the sealing member 4).

The first inner part 1a is also the chip mounting area 1d over which the semiconductor chip 8 is mounted, and is an area covered by the sealing member 4. Therefore, the first inner part 1a is not exposed from the sealing member 4.

The first outer part 1b is a part which is coupled to an electrode of a mounting board, for example, when the semiconductor device 6 is mounted over the mounting board. In other words, the first outer part 1b is an area exposed from the sealing member 4 and is an outer coupling terminal of the semiconductor device 6.

The first offset part 1c is a part of the first lead 1 which is curved so that the first inner part 1a is above the first outer part 1b (toward the upper surface of the sealing member 4). It is a curved portion which lies between the first inner part 1a and the first outer part 1b. The first offset part 1c is buried in the sealing member 4.

On the other hand, the second lead 2 includes a second inner part 2a, which is also a wire coupling area 2d, a second outer part 2b, and a second offset part 2c between the second inner part 2a and second outer part 2b. The second inner part 2a is located above the second outer part 2b (toward the upper surface of the sealing member 4).

The second inner part 2a is also the wire coupling area 2d to be coupled to the wire 3 electrically, and is an area covered by the sealing member 4. Therefore, the second inner part 2a is not exposed from the sealing member 4.

The second outer part 2b is a part which is coupled to an electrode of the mounting board, for example, when the semiconductor device 6 is mounted over the mounting board. In other words, the second outer part 2b is an area exposed from the sealing member 4 and is an outer coupling terminal of the semiconductor device 6.

The second offset part 2c is a part of the second lead 2 which is curved so that the second inner part 2a is above the second outer part 2b (toward the upper surface of the sealing member 4), and it is a curved portion which lies between the second inner part 2a and the second outer part 2b. The second offset part 2c is buried in the sealing member 4.

The wire 3 is, for example, a gold wire with a diameter of about 20 μm.

The sealing member 4 is formed, for example, by the transfer molding method. The material is, for example, epoxy resin or silicone resin.

### Semiconductor Device Manufacturing Method

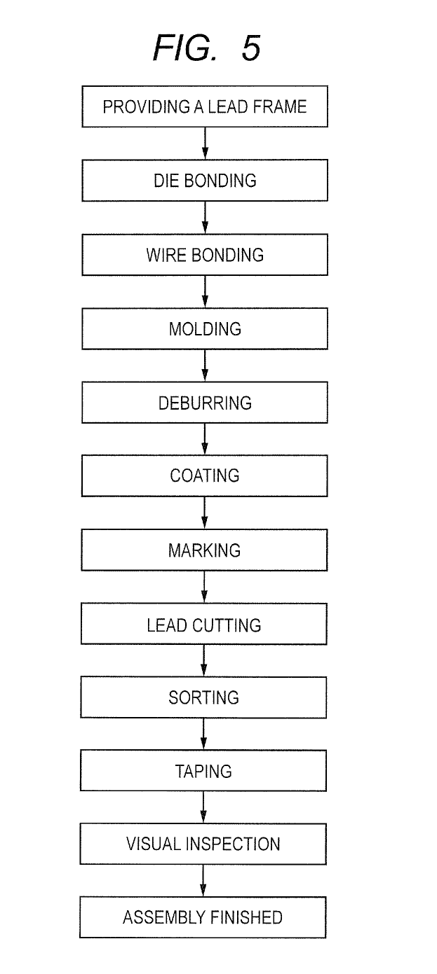

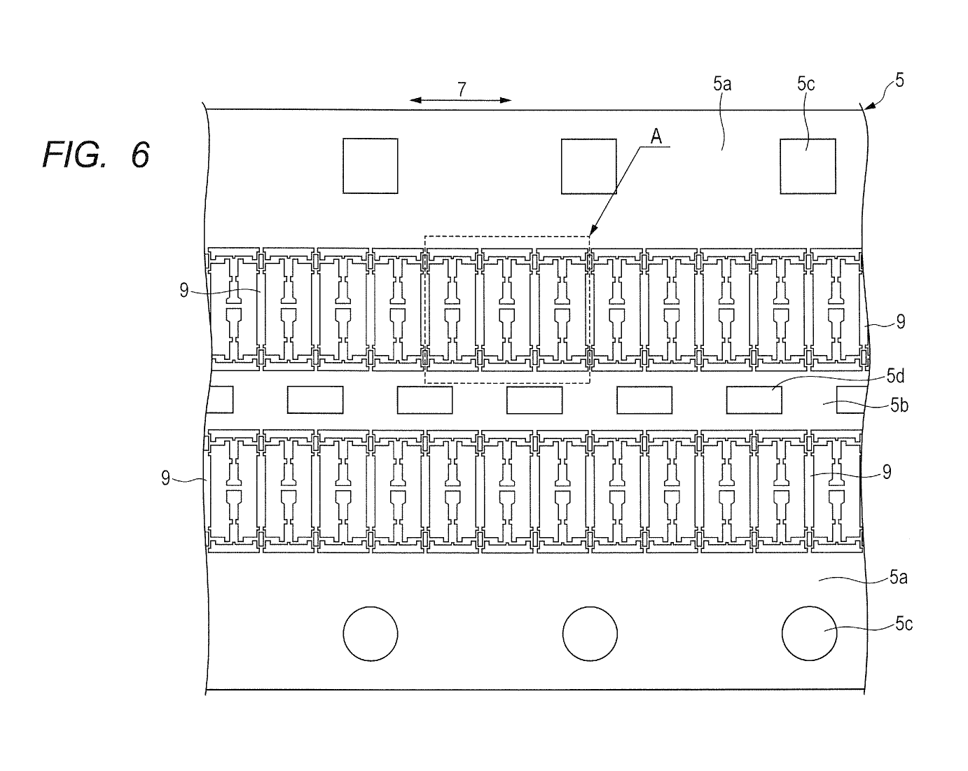

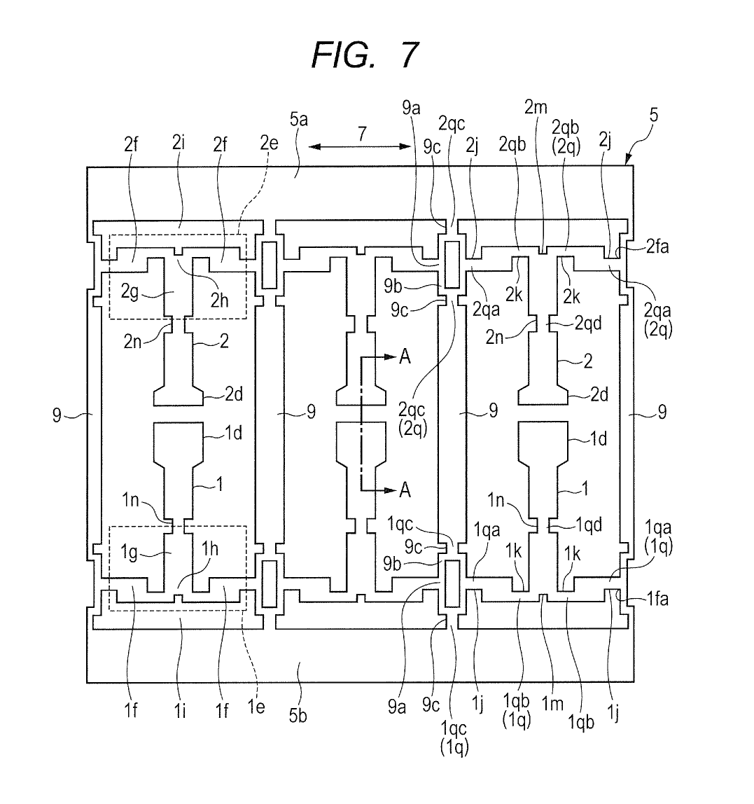

FIG. 5 is a flowchart showing an example of the sequence of assembling the semiconductor device shown in FIG. 1; FIG. 6 is a fragmentary plan view showing an example of the lead frame used to assemble the semiconductor device shown in FIG. 1; FIG. 7 is an enlarged fragmentary plan view showing an example of the structure of area A shown in FIG. 6; and FIG. 8 is a fragmentary sectional view showing an example of the structure, taken along the line A-A in FIG. 7.

Next, the method for manufacturing the semiconductor device 6 will be described according to the sequence shown in FIG. 5.

### 1. Step of Providing a Lead Frame

First, the step of providing a lead frame (FIG. 5) is carried out. The shape of the lead frame used to assemble the semiconductor device according to this embodiment will be described in detail referring to FIGS. 6 to 8.

The lead frame 5 used to assemble the semi conduct or device 6 according to this embodiment is a thin plate hoop. The assembling process is performed while the thin plate hoop is wound around a reel.

The lead frame 5 uses, as the bass material, a thermally conductive thin metal sheet of copper, iron, phosphor bronze (copper-based alloy containing tin (3.5-9.0%) and phosphor (0.03-0.35%)) or the like and its thickness is about 0.1 to 0.3 mm.

As shown in FIGS. 6 and 7, the hoop lead frame 5 as a metal frame is provided. The lead frame 5 shown in FIG. 6 is a multi-piece substrate. Assuming that the frame conveying direction 7 as the longitudinal direction corresponds to columns and the direction perpendicular to it corresponds to rows, unit frame areas, in each of which a single semiconductor device 6 (FIG. 1) is formed, are arranged, for example, two rows by a plurality of columns.

As shown in FIG. 6, the hoop lead frame 5 has frame parts 5a as outer frames at both ends along the conveying direction 7 and the frame parts 5a each have a plurality of thorough-holes 5c for feeding and positioning. Also a frame part 5b as an inner frame is provided between two rows of unit frame areas and the frame part 5b has a plurality of oblong through-holes 5d.

The lead frame 5 has a plurality of tie bars 9 as bar leads which connect the outer frame parts 5a and the inner frame part 5b. Each unit frame area is an area partitioned by tie bars 9.

Next, each unit frame area will be described in detail.

As shown in FIG. 7, each unit frame area is surrounded by the outer frame part 5a, the inner frame part 5b and the tie bars 9 on both sides. Each unit frame area includes a first lead (die island lead) 1 including a chip mounting area 1d, a second lead (post lead) 2 located opposite to the first lead 1, including a wire coupling area 2d, a first suspension lead 1e supporting the first lead 1, and a second suspension lead 2e supporting the second lead 2.

Furthermore, the first suspension lead 1e has a first part 1f joining the adjacent tie bars 9 and a second part 1g intersecting the first part 1f and joining the first lead 1, and the second suspension lead 2e has a third part 2f joining the adjacent tie bars 9 and a fourth part 2g intersecting the third part 2f and joining the second lead 2.

In other words, the first suspension lead 1e has the first part 1f extending along the frame part 5b and the second part 1g joining the first part 1f and extending along the tie bars 9, taking the shape of an inverted T as shown in FIG. 7.

On the other hand, the second suspension lead 2e has the third part 2f extending along the frame part 5a and the fourth part 2g joining the third part 2f and extending along the tie bars 9, taking the shape of T as shown in FIG. 7.

The first suspension lead 1e and the second suspension lead 2e each have a narrower part than at least any one of the first lead 1, second lead 2, and tie bar 9 (narrow parts 1q, 2q).

More specifically, a void 1i is made between the joint 1h of the first part 1f and second part 1g and the frame part 5b and a void 2i is made between the joint 2h of the third part 2f and fourth part 2g and the frame part 5a.

Furthermore, the first part 1f of the first suspension lead 1e has a first notch 1j in the joint 1fa with the tie bar 9, thereby forming a first narrow part 1qa. The third part 2f of the second suspension lead 2e has a first notch 2j in the joint 2fa with the tie bar 9, thereby forming a first narrow part 2qa.

Also, the first suspension lead 1e has a second notch 1k in the joint 1h between the first part 1f and the second part 1g, thereby forming a second narrow part 1qb. The second suspension lead 2e has a second notch 2k in the joint 2h between the third part 2f and the fourth part 2g, thereby forming a second narrow part 2qb.

In the lead frame 5 according to this embodiment, the second notch 1k is made on both sides of the second part 1g and the second notch 2k is made on both sides of the fourth part 2g. Alternatively, the second notch 1k and the second notch 2k may be made only on one side of the second part 1g and the fourth part 2g, respectively.

In addition, a third notch 1m is made on the frame side of the joint 1h between the first part 1f and second part 1g of the first suspension lead 1e and a third notch 2m is made on the frame side of the joint 2h between the third part 2f and fourth part 2g of the second suspension lead 2e.

In other words, as shown in FIG. 7, in the inverted T-shaped first suspension lead 1e, the first part 1f is coupled to the tie bars 9 on both sides and the first notch 1j and first narrow part 1qa are formed in the joint with each tie bar 9. The second part 1g of the first suspension lead 1e is coupled through a fifth notch 1n (through the fourth narrow part 1qd) to the first lead 1.

In the T-shaped second suspension lead 2e, the third part 2f is coupled to the tie bars 9 on both sides and the first notch 2j and first narrow part 2qa are formed in the joint with each tie bar 9. The fourth part 2g of the second suspension lead 2e is coupled through a fifth notch 2n (through the fourth narrow part 2qd) to the second lead 2.

Also, each tie bar 9 has an annular part 9b in the joint 9a with each of the first suspension lead 1e and the second suspension lead 2e. Preferably, the annular part 9b is long and narrow along the direction in which the tie bar 9 extends. In this embodiment, its shape is, for example, a rectangle which is long and narrow along the extension direction.

Each tie bar 9 has a fourth notch 9c and a third narrow part 1qc (2qc) on both sides of each annular part 9b.

As described above, in the lead frame 5 according to this embodiment, the suspension leads in each unit frame area have various notches in the suspension leads themselves, suspension lead joints and tie bars 9 coupled to the suspension leads. Consequently, they have a plurality of narrow lead parts (narrow parts 1q, 2q (first narrow parts 1qa, 2qa, second narrow parts 1qb, 2qb, third narrow parts 1qc, 2qc)).

Therefore, even if a stress which pulls the first lead 1 and second lead 2 is applied during the assembly of the semiconductor device 6, the narrow lead parts (narrow parts 1q, 2q) relieve the stress and reduce the stress on the interface between the first lead 1 and the sealing member 4 and the interface between the second lead 2 and the sealing member 4.

As shown in FIG. 8, the chip mounting area 1d of the first lead 1 is located in a higher position than the first outer part 1b through the first offset part 1c and similarly the wire coupling area 2d of the second lead 2 is located in a higher position than the second outer part 2b through the second offset part 2c. Consequently, the chip mounting area 1d of the first lead 1 and the wire coupling area 2d of the second lead 2 are almost at the same height.

This concludes the step of providing a lead frame.

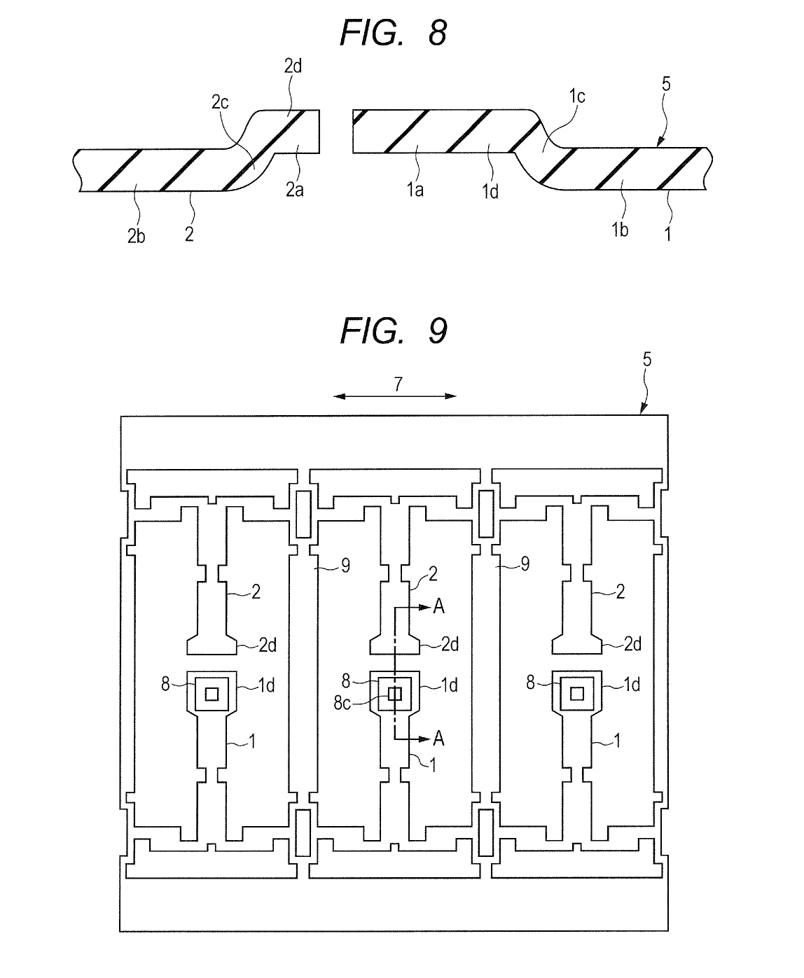

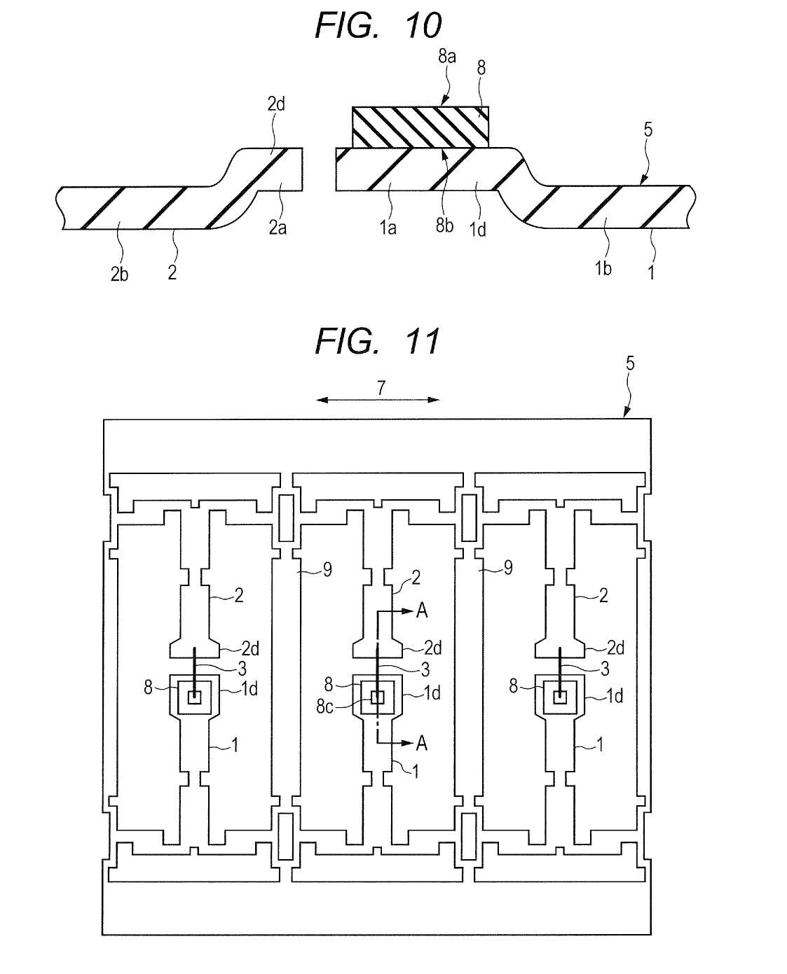

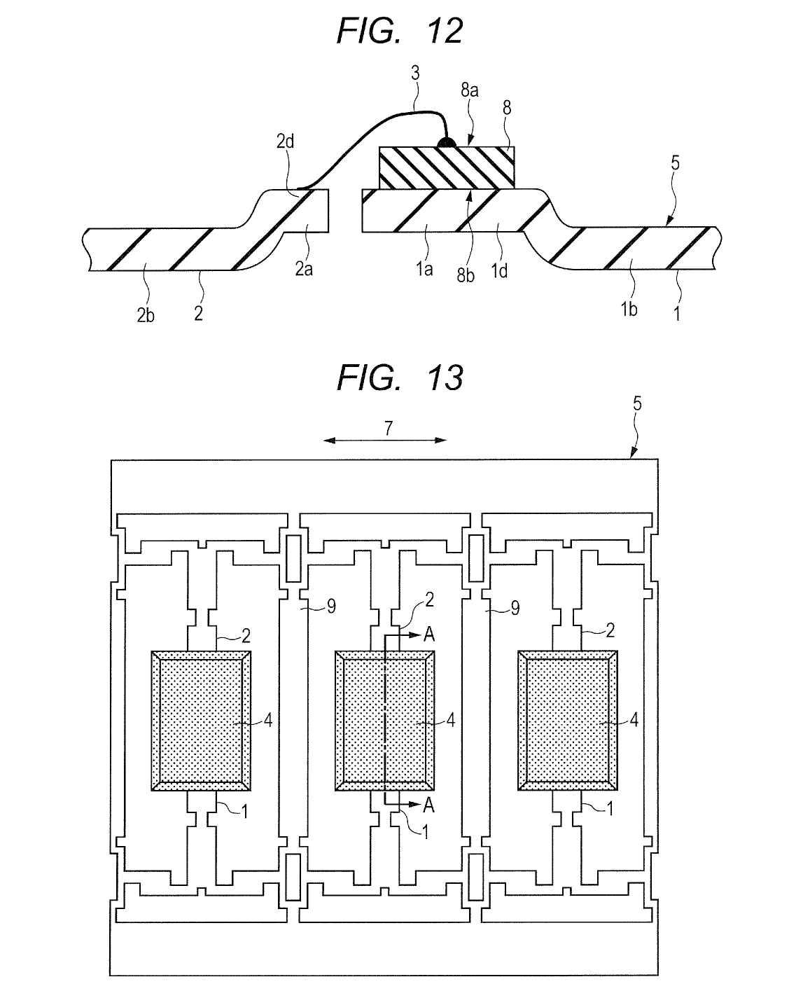

FIG. 9 is a fragmentary plan view showing an example of the structure after die bonding in the process of assembling the semiconductor device shown in FIG. 1; FIG. 10 is a fragmentary sectional view showing an example of the structure, taken along the line A-A in FIG. 9; FIG. 11 is a fragmentary plan view showing an example of the structure after wire bonding in the process of assembling the semiconductor device shown in FIG. 1; and FIG. 12 is a fragmentary sectional view showing an example of the structure, taken along the line A-A in FIG. 11.

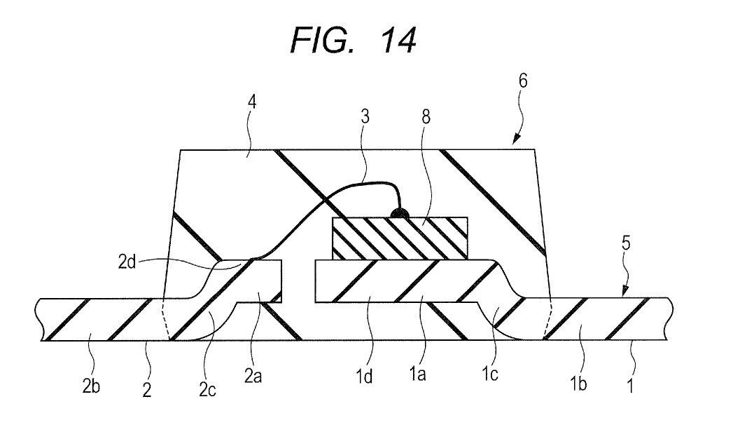

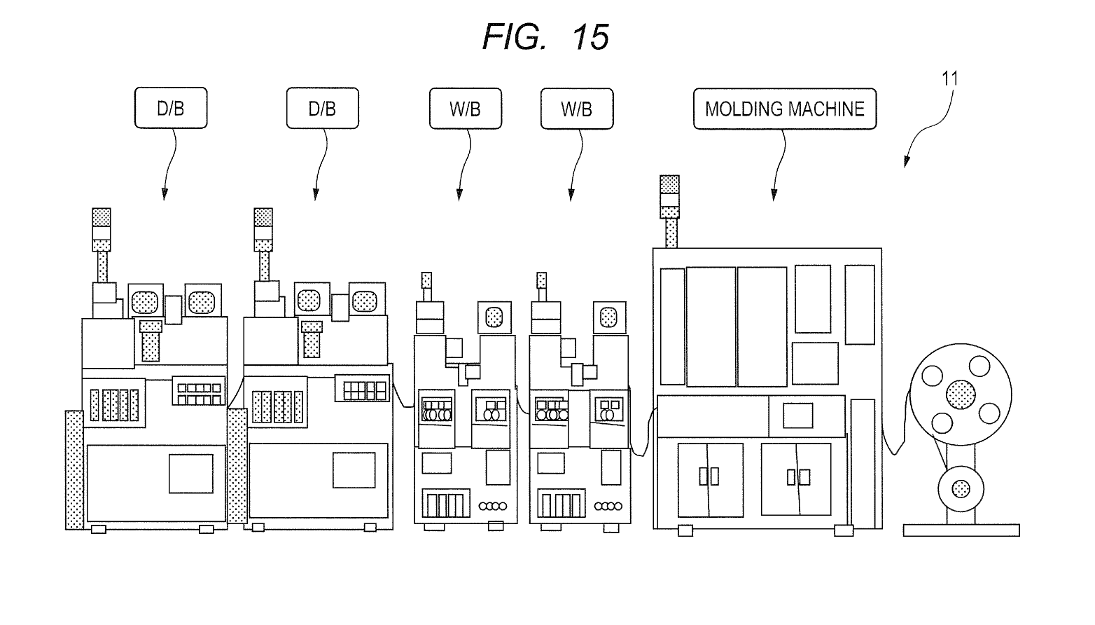

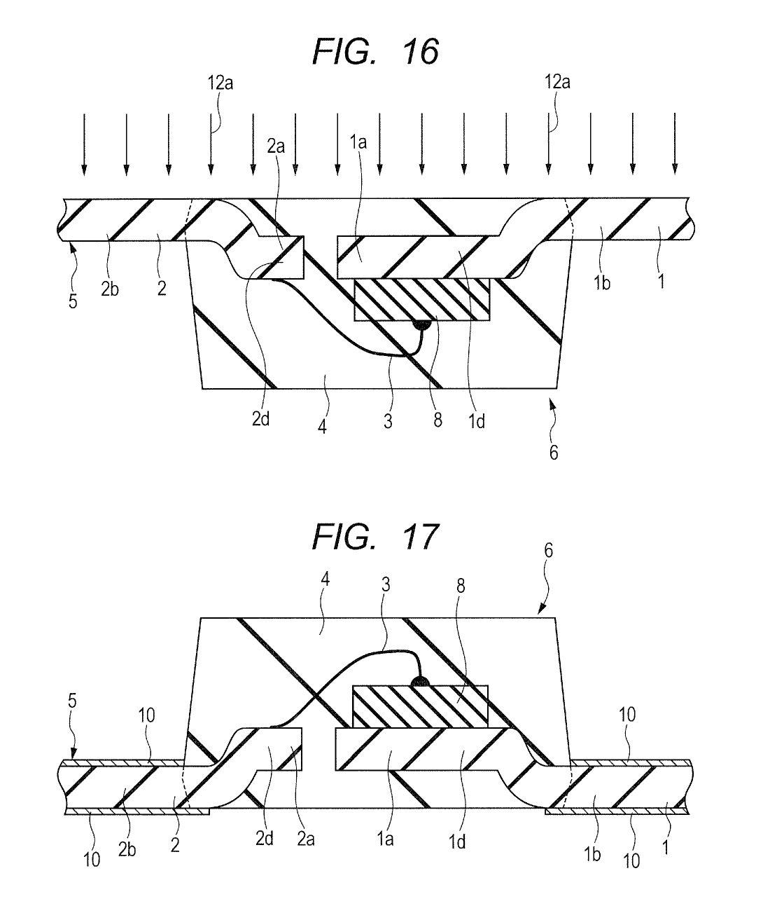

FIG. 13 is a fragmentary plan view showing an example of the structure after molding in the process of assembling the semiconductor device shown in FIG. 1; FIG. 14 is a fragmentary sectional view showing an example of the structure, taken along the line A-A in FIG. 13; FIG. 15 is a schematic view showing an example of the integrated apparatus used in the integrated hoop assembling line for the semiconductor device shown in FIG. 1; and FIG. 16 it is a fragmentary sectional view showing an example of the structure during debarring in the process of assembling the semiconductor device shown in FIG. 1.

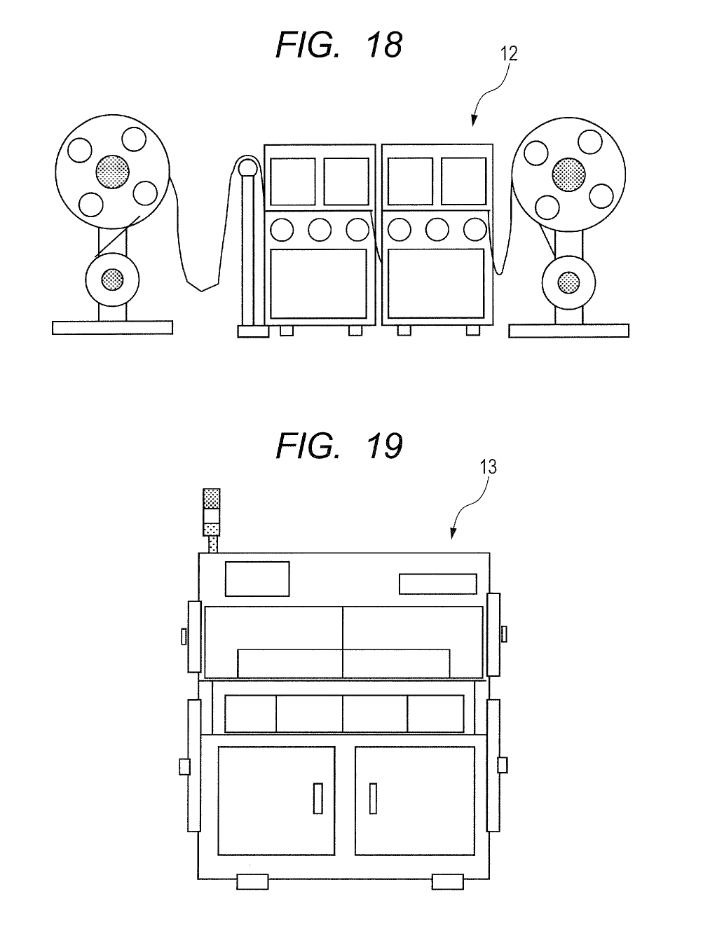

FIG. 17 is a fragmentary sectional view showing an example of the structure after coating in the process of assembling the semiconductor device shown in FIG. 1; FIG. 18 is a schematic view showing an example of the debarring apparatus used in the deburring line in the process of assembling the semiconductor device shown in FIG. 1; and FIG. 19 is a schematic view showing an example of the solder coating apparatus used in the coating line in the process of assembling the semiconductor device shown in FIG. 1.

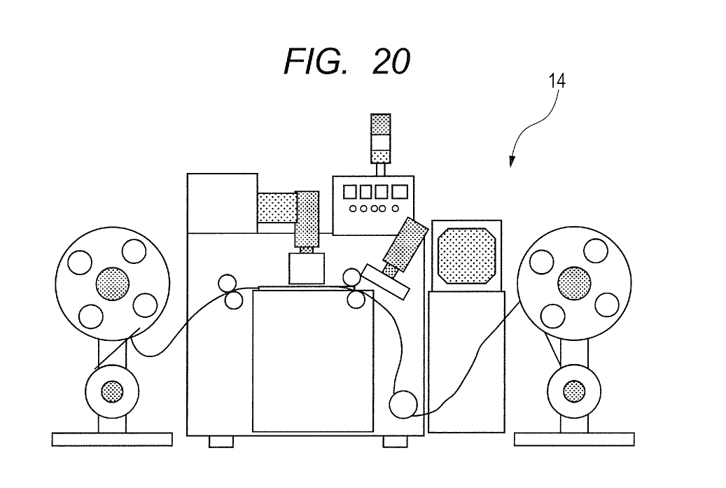

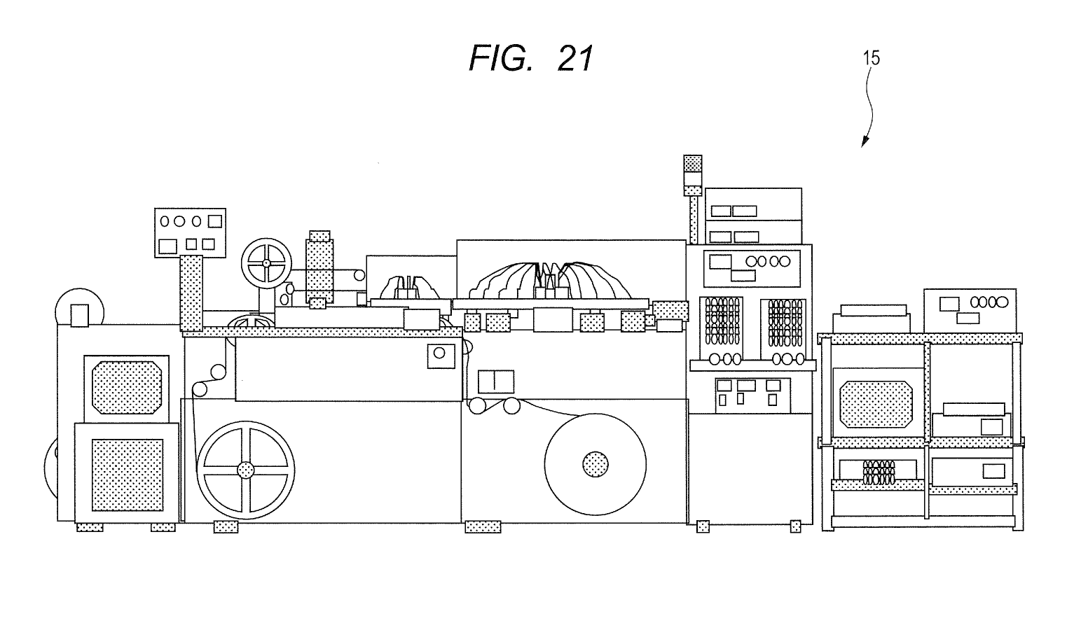

FIG. 20 is a schematic view showing an example of the laser marking apparatus used in the marking line in the process of assembling the semiconductor device shown in FIG. 1; and FIG. 21 is a schematic view showing an example of the integrated apparatus used in the lead cutting, sorting and taping line for assembling the semiconductor device shown in FIG. 1 using a hoop.

### 2. Die Bonding Step

After providing a lead frame, the die bonding (D/B) step (FIG. 5) is carried out. The die bonding step and the subsequent main steps in the semiconductor device manufacturing method according to this embodiment will be described, referring to the drawings which illustrate only three unit frame areas.

In the die bonding step, a semiconductor chip 8 is mounted over the chip mounting area 1d of the first lead 1 of the lead frame 5 as shown in FIGS. 9 and 10. More specifically, the upper surface of the chip mounting area 1d of the first lead 1 and the back electrode formed on the back surface 8b of the semiconductor chip 8 are bonded using, for example, a gold-tin (Au—Sn) eutectic alloy so that the semiconductor chip 8 is mounted over the upper surface of the chip mounting area 1d of the first lead 1. Alternatively, a paste adhesive (for example, silver (Ag) paste) or a film adhesive (DAF (Die Attach Film)) may be used for bonding instead of the Au—Sn eutectic alloy.

### 3. Wire Bonding Step

After die bonding, the wire bonding (W/B) step (FIG. 5) is carried out. In the wire bonding step, the pad electrode (electrode pad) 8c of the semiconductor chip 8 and the wire coupling area 2d of the second lead 2 are electrically coupled by a wire (conductive wire) 3 as shown in FIGS. 11 and 12. For example, by the nail head bonding (ball bonding) method which combines thermal compression and ultrasonic vibration, the pad electrode 8c formed on the main surface 8a of the semiconductor chip 8 and the wire coupling area 2d of the second lead 2 are electrically coupled by the wire 3.

The wire 3 is, for example, a gold wire with a diameter of 15-20 μm. The semiconductor chip 8 has a PIN (Positive Intrinsic Negative) diode, pn diode (for example, a switching diode or Zener diode) or Schottky barrier diode and two terminals can be taken out from the pad electrode 8c on the main surface 8a of the semiconductor chip 8 and the back electrode on the back surface 8b of the semiconductor chip 8.

### 4. Molding Step

After wire bonding, the molding step (FIG. 5) is carried out. In the molding step, the semiconductor chip 8, the wire 3, part of the first lead 1, and part of the second lead 2 are sealed with resin as shown in FIGS. 13 and 14. In other words, a sealing member 4 which protects the semiconductor chip 8, the wire 3, part of the first lead 1, and part of the second lead 2 is formed.

The sealing member 4 is made of resin such as epoxy resin or silicone resin. A forming die which has an upper mold and a lower mold is used to form the sealing member 4. For formation of the sealing member 4, first, molten resin is injected into the resin injection hole until the cavity in the forming die is filled with molten resin; then the molten resin is hardened. Consequently, a semiconductor device 6 in which a semiconductor chip 8 is mounted is formed in each unit frame area of the lead frame 5.

The first inner part 1a (chip mounting area 1d) and first offset part 1c of the first lead 1 are inside the sealing member 4. The first outer part 1b is exposed from the back and side surfaces of the sealing member 4 and functions as an outer coupling terminal of the semiconductor device 6.

Similarly, the second inner part 2a (wire coupling area 2d) and second offset part 2c of the second lead 2 are inside the sealing member 4. The second outer part 2b is exposed from the back and side surfaces of the sealing member 4 and functions as an outer coupling terminal of the semiconductor device 6.

The use of the integrated hoop assembling apparatus 11 shown in FIG. 15 for die bonding, wire bonding, and molding improves the assembling efficiency, though it is not always necessary to use such an integrated apparatus.

### 5. Deburring Step

After molding, the deburring step (FIG. 5) is carried out. In the deburring step, excessive resin (burr) which has overflown through microscopic gaps of the forming die and has adhered to the surfaces of the first outer part 1b of the first lead 1 and the second outer part 2b of the second lead 2 in the molding step is removed as shown in FIG. 16.

Burrs are removed using the debarring apparatus 12 shown in FIG. 18 by a water jet method in which high-pressure liquid 12a of hundreds of kilograms per square centimeter (high-pressure water) is sprayed through a nozzle onto the lower surface (mounting surface) of the sealing member 4, the first outer part 1b and second outer part 2b which are exposed from the lower surface of the sealing member 4, as shown in FIG. 16. Alternatively, electrolytic treatment may be adopted to let burrs float.

In order to remove burrs completely, the liquid honing method which sprays a liquid containing resin beads or glass beads (filler) may be adopted instead of high-pressure water. In this case as well, the sprayed liquid can be prevented from peeling the sealing member A.

### 6. Coating Step

After deburring, the coating step (FIG. 5) is carried out. In the coating step, coating is made with the semiconductor device 6 formed in the lead frame 5 as shown in FIG. 17. For example, using a solder coating apparatus 13 as shown in FIG. 19, a solder coating 10 is made on the surface of the lead frame 5 as a coating layer as shown in FIG. 17. More specifically, for example, a solder coating 10 of a tin-copper (Sn—Cu) alloy or tin-lead (Sn—Pb) alloy, for example, with a thickness of 10 μm or less is made on the surfaces of the first outer part 1b of the first lead 1 and the second outer part 2b of the second lead 2 which both protrude from the sealing member 4.

At this time, the solder coating 10 also covers the fifth notches 1n and 2n of the first lead 1 and second lead 2 as shown in FIG. 7.

Since burrs are completely removed from the surfaces of the first outer part 1b of the first lead 1 and the second outer part 2b of the second lead 2 in the deburring step and the surfaces are exposed, the solder coating 10 is made uniformly all over the surfaces.

### 7. Marking Step

After coating, the marking step (FIG. 5) is carried out. In the marking step, a desired mark (printing) is made on the surface of the sealing member 4. For example, using a laser marking machine 14 as shown in FIG. 20, the mark indicating the product type or model number is made by laser irradiation of the surface of the sealing member 4.

### 8. Lead Cutting Step

After marking, the lead cutting step (FIG. 5) is carried out. In the lead cutting step, the first outer part 1b of the first lead 1 and the second outer part 2b of the second lead 2 are cut to make separate semiconductor devices 6. In other words, semiconductor devices 6 are separated from the frame parts 5a and 5b of the lead frame 5 shown in FIG. 6.

### 9. Sorting Step

After lead cutting, the sorting step (FIG. 5) is carried out. In the sorting step, an electric characteristic test is conducted to determine whether each semiconductor device 6 is a non-defective product or a defective product.

### 10. Taping Step

After sorting, the taping step (FIG. 5) is carried out. In the taping step, taping is done only on the semiconductor devices 6 which have been sorted as non-defective.

The efficiency in assembling the semiconductor device 6 can be improved by using the integrated apparatus 15 for lead cutting, sorting, and taping as shown in FIG. 21 in the lead cutting, sorting, and taping steps, though it is not always necessary to use such an integrated apparatus.

### 11. Visual Inspection Step

After taping, the visual inspection (FIG. 5) is conducted. In the visual inspection step, each semiconductor device 6 is visually checked using, for example, a visual inspection apparatus which has an image processing device. A semiconductor device 6 which has been judged as visually defective in the visual inspection is removed.

This concludes the process of assembling the semiconductor device 6.

Next, the advantageous effects of the method for manufacturing the semiconductor device 6 according to this embodiment will be described.

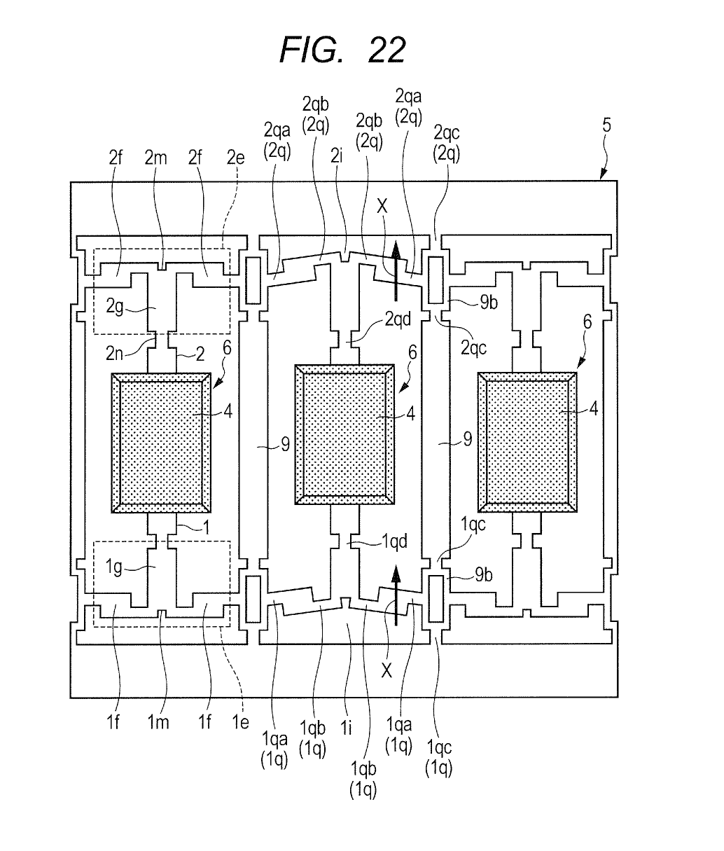

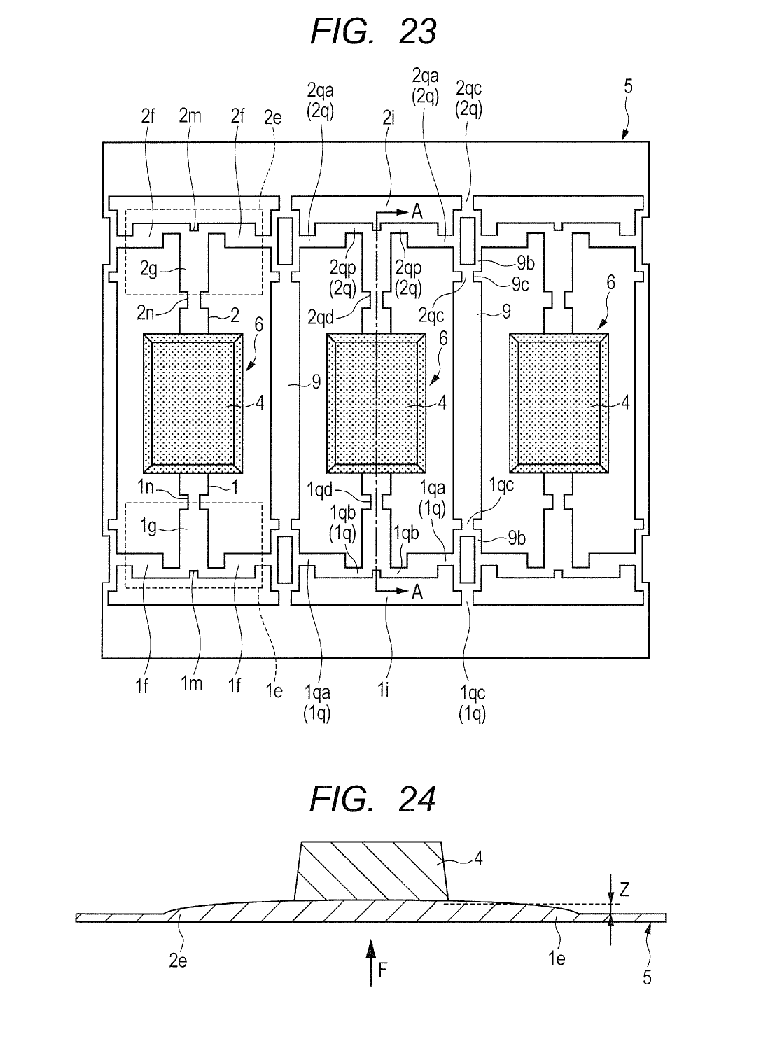

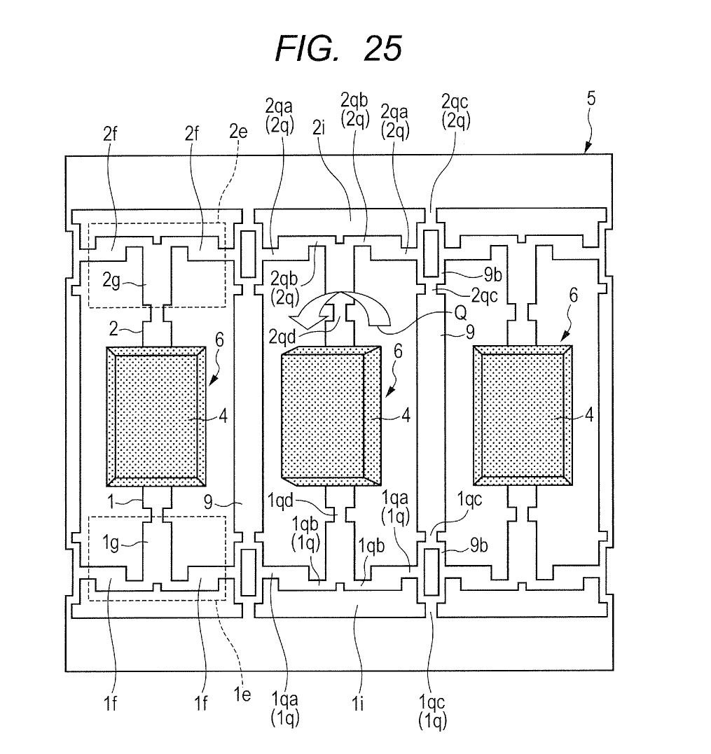

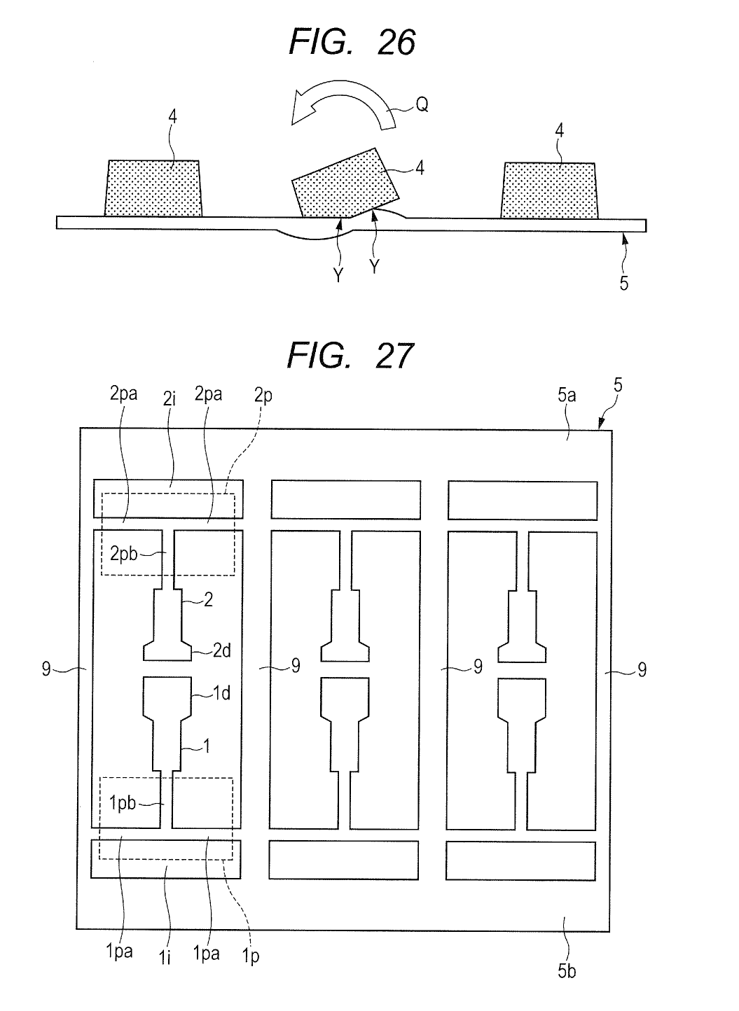

FIG. 22 is a fragmentary plan view showing an advantageous effect of the process of assembling the semiconductor device shown in FIG. 1; FIG. 23 is a fragmentary plan view showing an advantageous effect of the process of assembling the semiconductor device shown in FIG. 1; and FIG. 24 is a side view showing an advantageous effect of the lead structure shown in FIG. 23. FIG. 25 is a fragmentary plan view showing an advantageous effect of the process of assembling the semiconductor device shown in FIG. 1 and FIG. 26 is a side view showing an advantageous effect of the lead structure shown in FIG. 25.

When the lead frame 5 according to this embodiment is used, if a stress which pulls the first lead 1 or second lead 2 is applied after the molding step in the process of assembling the semiconductor device 6, the stress is reduced by the narrow parts 1q and 2q (first narrow parts 1qa, 2qa, second narrow parts 1qb, 2qb, and third narrow parts 1qc, 2qc) of the suspension leads (first suspension lead 1e or second suspension lead 2e).

FIG. 22 illustrates an effect on horizontal displacement. Since the voids 1i and 2i are made outside the first suspension lead 1e and second suspension lead 2e respectively and also the suspension leads have the narrow parts 1q and 2q as shown in FIG. 22, the second part 1g of the first suspension lead 1e and the fourth part 2g of the second suspension lead 2e can move toward the voids 1i and 2i.

More specifically, if a stress which pulls the second suspension lead 2e outwards is applied, the T-shaped second suspension lead 2e can move in a manner to let the fourth part 2g protrude slightly toward the void 2i (X direction) because the T-shaped second suspension lead 2 has the first narrow parts 2qa and second narrow parts 2qb. At the same time, the second part 1g of the opposite first suspension lead 1e moves slightly toward the X direction, following the movement of the first suspension lead 1e.

In other words, as the T-shaped second suspension lead 2e deforms and moves toward the X direction, the inverted T-shaped first suspension lead 1e also deforms and moves toward the X direction. Specifically, the second suspension lead 2e joined to the second lead 2 and the first suspension lead 1e joined to the first lead 1 deform and move slightly toward the X direction due to the narrow parts 1q and 2q, respectively.

The deformation of the first suspension lead 1e and the second suspension lead 2e absorbs the stress and thereby reduces the stress on the interface between the sealing member 4 and the lead (first lead 1 and second lead 2).

In other words, the stress generated on the first lead 1 and second lead 2 and on the base of the sealing member 4 can be relieved, thereby reducing the possibility of package cracking or package chipping.

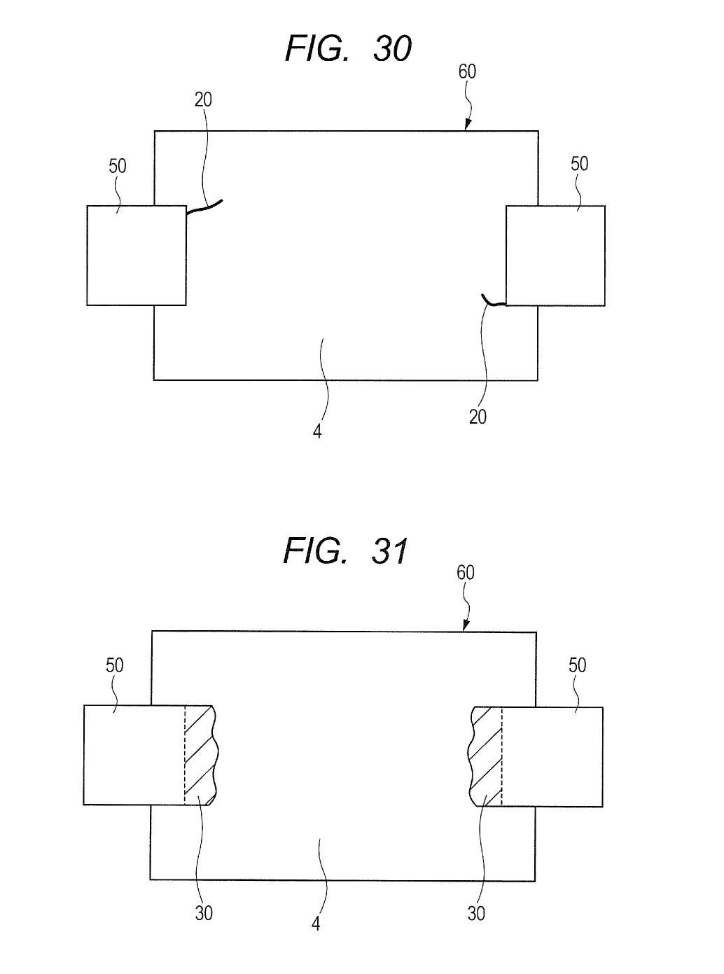

As a result, cracking 20 (FIG. 30.) and chipping 30 (FIG. 31) are reduced and the reliability of the semiconductor device 6 is enhanced.

Even if the first lead 1 is pulled outwards (toward the direction opposite to the X direction), the first suspension lead 1e and the second suspension lead 2e can move toward the direction opposite to the X direction and the stress can be relieved in similarly.

Furthermore, in the lead frame 5, the tie bars 9, joined to the first suspension lead 1e and the second suspension lead 2e, has annular parts 9b and third narrow parts 1qc and 2qc. Each annular part 9b is a narrow part made by narrow leads and the annular part 9b and the third narrow parts 1qc and 2qc on both sides thereof relieve the stress on the first suspension lead 1e and the second suspension lead 2e.

This further relieves the stress generated on the first lead 1 and second lead 2 and on the base of the sealing member 4, thereby reducing the possibility of package cracking or package chipping. As a result, the reliability of the semiconductor device 6 is further enhanced.

FIGS. 23 and 24 illustrate an effect on displacement in the vertical direction (thickness direction of the sealing member 4). As shown in FIG. 24, if load F is applied to the lower surface of the lead frame 5, for example, during assembly or transportation as shown in FIG. 24, the sealing member 4 is pushed up in the direction of the load F.

In the lead frame 5 according to this embodiment, the first suspension lead 1e has first narrow parts 1qa and second narrow parts 1qb and the second suspension lead 2e has first narrow parts 2qa and second narrow parts 2qb, as shown in FIG. 23.

Therefore, if the load F is applied, the first narrow parts 1qa and second narrow parts 1qb and the first narrow parts 2qa and second narrow parts 2qb move, causing deformation of the first suspension lead 1e and the second suspension lead 2e.

This absorbs the stress generated by the load F and reduces the amount of displacement Z of the sealing member 4 in the direction of the load F as shown in FIG. 24.

As a result, the stress on the interface between the sealing member 4 and the leads (first lead 1 and second lead 2) can be reduced. In other words, the stress generated on the first lead 1 and second lead 2 and on the base of the sealing member 4 can be relieved, thereby reducing the possibility of package cracking or package chipping.

As a result, cracking 20 (FIG. 30) and chipping 30 (FIG. 31) are reduced and the reliability of the semiconductor device 6 is enhanced.

FIGS. 25 and 26 illustrate an effect on the direction of rotation Q around the lead (post lead or die island lead) as an axis. For example, if the first lead 1 or second lead 2 rotates during assembly or transportation, a stress is applied to the sealing member 4 in the rotation direction Q. The stress is applied to parts Y shown in FIG. 26.

In the lead frame 5 according to this embodiment, the first suspension lead 1e has first narrow parts 1qa and second narrow parts 1qb and the second suspension lead 2e has first narrow parts 2qa and second narrow parts 2qb, as shown in FIG. 25.

Therefore, if the sealing member 4 is going to rotate in the rotation direction Q, the first narrow parts 1qa and second narrow parts 1qb and the first narrow parts 2qa and second narrow parts 2qb move, causing deformation of the first suspension lead 1e and the second suspension lead 2e.

This absorbs the stress on the parts Y (FIG. 26) and thereby relieves the stress on the interface between the first lead 1 and the sealing member 4 and the interface between the second lead 2 and the sealing member 4 as shown in FIG. 25. This protects the bass of the first lead 1 (interface between the sealing member 4 and the first lead 1) and the base of the second lead 2 (interface between the sealing member 4 and the second lead 2) where cracking 20 may start.

Therefore, the reliability of the semiconductor device 6 is enhanced.

The presence of the annular parts 9b and third narrow parts 1qc and 2qc in the tie bars 9 joined to the first suspension lead 1e and the second suspension lead 2e relieves the stress on the interface between the sealing member 4 and the leads even in the vertical direction (thickness direction of the sealing member 4) and in the rotation direction Q (rotation θ).

Therefore, the possibility of package cracking or package chipping is further reduced and the reliability of the semiconductor device 6 is further enhanced.

### Variations

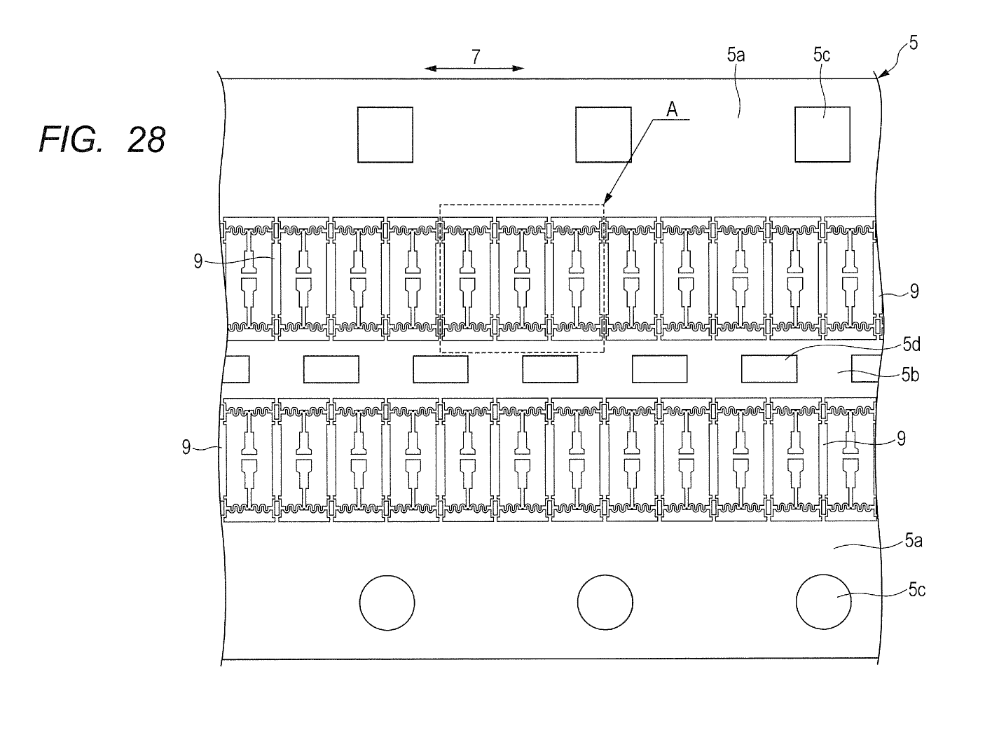

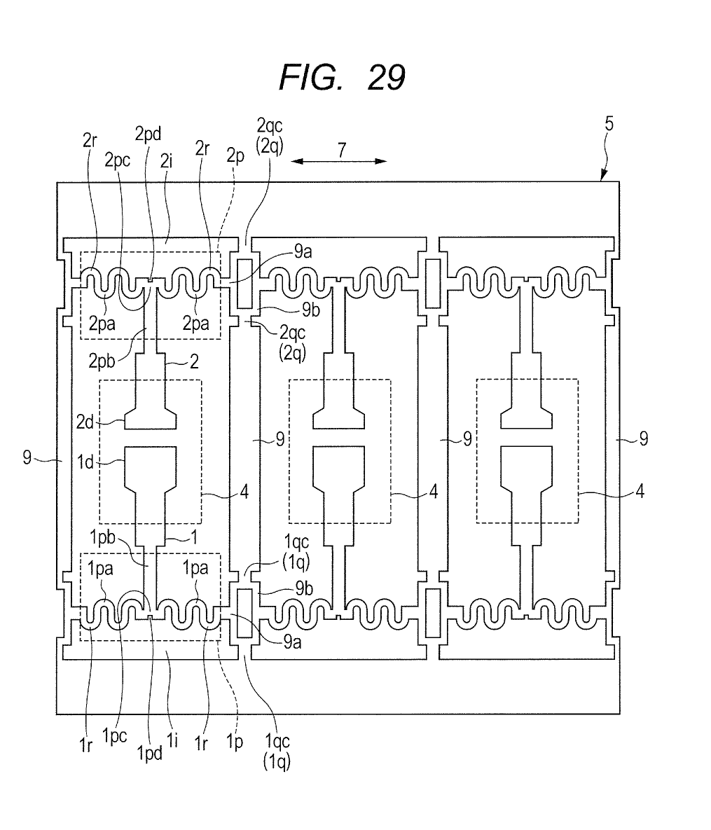

FIG. 27 is a fragmentary plan view showing a first variation of the lead frame used to assemble the semiconductor device according to the embodiment; FIG. 28 is a fragmentary plan view showing a second variation of the lead frame used to assemble the semiconductor device according to the embodiment; and FIG. 29 is an enlarged fragmentary plan view showing an example of the structure of area A shown in FIG. 28.

The first variation shown in FIG. 27 includes a first support lead 1p and a second support lead 2p which are equivalent, to suspension leads, in which the first support lead 1p is inverted T-shaped and the second support lead 2p is T-shaped.

The first support lead 1p has a first part 1pa joining the adjacent tie bars (bar leads) 9 and a second part 1pb joining the first lead 1. The second support lead 2p has a third part 2pa joining the adjacent tie bars 9 and a fourth part 2pb joining the second lead 2.

The first support lead 1p and the second support lead 2p each have a narrow part which has a smaller lead width than at least any one of the first lead 1, second lead 2 and tie bar 9.

In the frame structure shown in FIG. 27, the whole first support lead 1p and the whole support lead 2p have a smaller lead width than the first lead 1, second lead 2 and tie bar 9. In other words, the whole first support lead 1p and the whole second support lead 2p are narrow parts.

Furthermore, a void 1i is made between the first part 1pa of the first support lead 1p and the frame part 5b and a void 2i is made between the third part 2pa of the second support lead 2p and the frame part 5a.

Consequently, even if a stress which pulls the second support lead 2p outwards is applied, the T-shaped second support lead 2p can move in a manner to let the fourth part 2pb protrude slightly toward the void 2i because it is a narrow part. At the same time, the second part 1pb of the opposite first support lead 1p moves slightly, following the movement of the first support lead 1p.

In short, since the second support lead 2p and the first support lead 1p themselves are narrow parts, the inverted T-shaped first support lead 1p also deforms and moves as the T-shaped second support lead 2p deforms and moves.

The deformation of the first support lead 1p and the second support lead 2p absorbs the stress and thereby reduces the stress on the interface between the sealing member 4 and the lead (first lead 1 and second lead 2).

In other words, the stress generated on the first lead 1 and second lead 2 and on the bass of the sealing member 4 can be relieved, thereby reducing the possibility of package cracking or package chipping. As a result, cracking 20 (FIG. 30) and chipping 30 (FIG. 31) are reduced and the reliability of the semi conductor device 6 is enhanced.

In the frame structure of the second variation shown in FIGS. 28 and 29, the first part 1pa of the first support lead 1p has a crank part 1r and the third part 2pa of the second support lead 2p has a crank part 2r.

Consequently, even if a stress which pulls the second support lead 2p outwards is applied, the T-shaped second support lead 2p (FIG. 29) can move in a manner to let the fourth part 2pb protrude slightly toward the void 2i because its third part 2pa has the crank part 2r. At the same time, the second part 1pb of the opposite first support lead 1p moves slightly, following the movement of the first support lead 1p.

In short, as the T-shaped second support lead 2p deforms and moves, the inverted T-shaped first support lead 1p also deforms and moves.

The presence of the crank parts 2r and 1r enables the first support lead 1p and second support lead 2p to deform so as to absorb the stress, thereby reducing the stress on the interface between the sealing member 4 and the lead (first lead 1 and second lead 2).

In the frame structure shown in FIG. 29, a notch 1pd is made on the frame side of the joint 1pc between the first part 1pa and second part 1pb of the first support lead 1p and a notch 2pd is made on the frame side of the joint 2pc between the third part 2pa and fourth part 2pb of the second support lead 2p.

Furthermore, the tie bar 9 has a slit-like annular part 9b in the joint 9a with the first part 1pa of the first support lead 1p and in the joint 9a with the third part 2pa of the second support lead 2p.

Narrow parts (third narrow parts 1qc, 2qc) are formed on both sides of each annular part 9b of the tie bar 9.

The presence of the notches 1pd, 2pd, annular parts 9b, and narrow parts (third narrow parts 1qc, 2qc) further relieves the applied stress and further relieves the stress on the first support lead 1p and second support lead 2p.

This further relieves the stress generated on the first lead 1 and second lead 2 and on the base of the sealing member 4, thereby reducing the possibility of package cracking or package chipping. As a result, the reliability of the semiconductor device is further enhanced.

The invention made by the present inventors has been so far explained concretely in reference to the preferred embodiments thereof. However, the invention is not limited thereto and it is obvious that these details may be modified in various ways without departing from the spirit and scope thereof.

The narrow parts of the first suspension lead 1e, second suspension lead 2e, first support lead 1p, and second support lead 2p in the above embodiments need not be narrower (smaller in lead width) than all of the first lead 1, second lead 2 and tie bar 9. In other words, they have only to be thinner (narrower) than at least one of the first lead 1, second lead 2, and tie bar 9.

What is claimed is:

1. A semiconductor device manufacturing method comprising the steps of:
(a) providing a lead frame having a first lead including a chip mounting area, a second lead located opposite to the first lead, a first suspension lead supporting the first lead, and a second suspension lead supporting the second lead;
(b) after the step (a), mounting a semiconductor chip over the chip mounting area of the lead frame;
(c) after the step (b), coupling an electrode pad of the semiconductor chip and the second lead electrically by a conductive wire; and
(d) after the step (c), sealing the semiconductor chip, the conductive wire, part of the first lead, and part of the second lead with resin;
wherein the lead frame has frame parts at both ends along a transportation direction thereof and a plurality of bar leads joining the frame parts at the both ends,
wherein the first suspension lead has a first part joining the adjacent bar leads and a second part intersecting the first part and joining the first lead,
wherein the second suspension lead has a third part joining the adjacent bar leads and a fourth part intersecting the third part and joining the second lead, and
wherein the first suspension lead and the second suspension lead each have a narrow part with a smaller width than at least any one of the first lead, the second lead, and the bar lead.

2. The semiconductor device manufacturing method according to claim 1, wherein a void is made between a joint of the first part and the second part and the frame part and a void is made between a joint of the third part and the fourth part and the frame part.

3. The semiconductor device manufacturing method according to claim 1, wherein the first part of the first suspension lead has a first notch in a joint with the bar lead and the third part of the second suspension lead has a first notch in a joint with the bar lead.

4. The semiconductor device manufacturing method according to claim 1, wherein the first suspension lead has a second notch in a joint between the first part and the second part and the second suspension lead has a second notch in a joint between the third part and the fourth part.

5. The semiconductor device manufacturing method according to claim 4, wherein the second notch is made on both sides of the second part and on both sides of the fourth part.

6. The semiconductor device manufacturing method according to claim 1, wherein the first suspension lead has a third notch on a frame side of a joint between the first part and the second part and the second suspension lead has a third notch on a frame side of a joint between the third part and the fourth part.

7. The semiconductor device manufacturing method according to claim 1, wherein the bar lead has an annular part at a joint with the first suspension lead and at a joint with the second suspension lead.

8. The semiconductor device manufacturing method according to claim 7, wherein the bar lead has a fourth notch on both sides of the annular part.

3. The semiconductor device manufacturing method according to claim 1, further comprising the step of:
(e) after the step (d), making a solder coating on a surface of the lead frame,
wherein in the step (e), the solder coating coves a fifth notch in the first lead and a fifth notch in the second lead.

10. A semiconductor device manufacturing method comprising the steps of:
(a) providing a lead frame having a first lead including a chip mounting area, a second lead located opposite to the first support lead supporting the first lead, and a second support lead supporting the second lead;
(b) after the step (a), mounting a semiconductor chip over the chip mounting area of the lead frame;
(c) after the step (b), coupling an electrode pad of the semiconductor chip and the second lead electrically by a conductive wire; and
(d) after the step (c), sealing the semiconductor chip, the conductive wire, part of the first lead, and part of the second lead with resin;
wherein the lead frame has frame parts at both ends along a transportation direction thereof and a plurality of bar leads joining the frame parts at the both ends,
wherein the first support lead has a narrow part or crank, part which joins the adjacent bar leads and have a smaller width than at least any one of the first lead and the bar lead, and
wherein the second support lead has a narrow part or crank part which joins the adjacent bar leads and has a smaller width than at least any one of the second lead and the bar lead.

11. The semiconductor device manufacturing method according to claim 13,
wherein the first support lead has a first part joining the bar leads and a second part joining the first lead, and
wherein the second support lead has a third part joining the bar leads and a fourth part joining the second lead.

12. The semiconductor device manufacturing method according to claim 11, wherein a void is made between the first part of the first support lead and the frame part and a void is made between the third part of the second support lead and the frame part.

13. The semiconductor device manufacturing method according to claim 11, wherein the bar lead has an annular part at a joint with the first part of the first support lead and an annular part at a joint with the third part of the second support lead.

14. The semiconductor device manufacturing method according to claim 13, wherein the narrow part is formed on both sides of the annular part of the bar lead.

15. The semiconductor device manufacturing method according to claim 11, wherein the first support lead has a notch on a frame side of a joint between the first part and the second part and the second support lead has a notch on a frame side of a joint between the third part and the fourth part
